(19) United States
(12) Patent Application Publication
(10) Pub. No.: US 2005/0268195 A1
(43) Pub. Date: Dec. 1, 2005

(54) Apparatus and method for improving emulation speed of high-level languages in on-chip emulation systems

(76) Inventors: Morten W. Lund, Skjetnemarka (NO); Gaute Myklebust, Trondheim (NO); Frank Langtind, Trondheim (NO)

Correspondence Address: SCHNECK & SCHNECK, P.O. BOX 2-E, SAN JOSE, CA, 95109-0005, US

(21) Appl. No.: 10/837,483

(22) Filed: Apr. 29, 2004

(51) Int. Cl. G06F 11/00; G01R 31/28

(52) U.S. Cl. 714/741

(57) ABSTRACT

Methods and apparatus for stepping-over and stepping-out of functions encountered during program execution on a target processor during debug operations are implemented within a combination of an emulator and a debug module. By having communication and storage devices available on-chip in the debug module, stepping and address compare details are conducted local to the processor at hardware speeds. The methods correctly determine necessary algorithmic steps to accommodate recursive and nested function calls without intervention by a combination of a host debug platform and a debug software application. This avoids the amount of time that would otherwise be necessary to cycle communications to the debug host level to accomplish the same processes. Override instructions for the target processor can be inserted and alternate memory locations jumped to under control of the same debug module, thereby using hardware resources efficiently.

### TECHNICAL FIELD

The present invention relates to the field of debugging software during code development. More specifically, the present invention relates to hardware control of operations of single stepping and break point determination while debugging software running on a processor.

### BACKGROUND ART

Software or code development is a process of referencing a specification for an intended program, writing programming statements in a source code language, then compiling, linking, and loading a final executable code file and debugging a result. A debugging process will determine if and when proper program behavior has been achieved. If the desired result is not achieved, then the entire process is iterated with updates to the source code until a debug session reveals that the code is operating with the proper behavior desired in the original specification.

A debugger can be a stand-alone application or an application that is merged into an integrated development environment (IDE) with the rest of a software development tool chain. The software development tool chain may include a source code editor, a syntactical code checker, a compiler, a linker, and a loader, which produces the executable code file. The debugger provides a plurality of views of the processor and programming environment. Each view is presented in a window when a graphical user interface (GUI) is incorporated. A window shows a source-level view in a source code editor. Other views of the processor may include a program stack, which is a data structure that contains, and saves for return, a state of the processor when a new routine is jumped to, an assembly-level view (or a machine code view), a view of a plurality of various registers, a view of the register contents to ascertain data and variable values, a debug information view generated by the compiler. With these views available throughout the operation of the processor on the program being developed, the behavior can be retrieved by interrogation and traced so that the programmer can determine if the desired response is being achieved.

The debugger can read and write the executable code space of a processor to be debugged. At the location for a break point to be set, an original instruction is removed and saved. A break instruction, for example, a special operational code (opcode) or a non-operation instruction (no-op), is placed at the original instruction location to affect a break in operation. Code execution is then started at a desired location. When execution reaches the newly set break point position, the processor will stop. In order for any execution to continue, through either continued running or single stepping, the original instruction is retrieved from storage and placed in the original location. Execution can proceed and the original intended program behavior results.

Information relating to attempts to improve the art in this area can be found in existing art. For example, U.S. Pat. No. 5,740,413, to Alpert et al., describes a method and apparatus for providing address break points, branch break points, and single stepping. Further, U.S. Patent Application Publication No. 2002/0170030, to Halcomb et al., describes downloading programs into a programmable logic device (PLD) for mimicking processor operations in an emulation operation.

However, these references suffer a disadvantage in one or more areas: none allow original code to override special break instructions that have been written into program storage to represent break points when restarting or single stepping code, none allow break point manipulation at hardware speeds, none handles a step out function where recursive functions may be incorporated, none manage break points without involving the debugger directly in detailed stepping methods and none handle these aspects from an on-chip debugging situation.

Under the existing art, stepping through programs involves significant amounts of emulator intervention, performing a small number of steps and reading out the status of the processor to determine what to do next. Performing step-over and step-out operations that also correctly handle recursive calls can consume vast amounts of time if no hardware support is available in an on-chip debug module. What is needed is a method that allows execution of the majority of the instructions at full speed while performing step-over and step-out functions. Since these functions can require millions of processor instructions to complete, considerable execution benefit is gained. Furthermore, as an on-chip debug module adds cost to each device it is added to, being able to reuse existing hardware in formation of the on-chip debug module would be a great benefit.

### DISCLOSURE OF THE INVENTION

The present invention is directed to an apparatus for rapidly stepping through programming statements while debugging. The apparatus is a debug module for managing execution of software on a target processor during debug. The debug module contains a physical layer configured to connect the debug module to an emulator for the exchange of debug information. The debug module also contains an access control layer, which implements general access to the debug module. The access control layer is configured to receive communication control commands, register identification, and mode control commands from the emulator. The debug module also contains an application layer to manage operation of the target processor. The application layer is configured to receive commands, mode settings, and processor instruction data from the emulator.

The present invention is also directed to a method for stepping over function calls in software executing on a target processor. This method involves setting one or more break points in the software to be executed by updating the program storage as required by the break points set, setting the debug mode to step-over, scanning the program storage from the current program location to find the next sequential symbolic break point, setting the contents of the debug register to any break point address found in the scanning step or to a maximum offset from current program location if no breakpoint address found, setting the program counter to the point of desired execution in the program, starting execution of said program, halting program execution when the program counter equals the contents of the debug register, a break instruction is executed or a specific change in flow is encountered. If no break instruction or symbolic breakpoint is found at the current program counter, the process is repeated from the scanning stage, otherwise the process is completed by reading and correcting the program counter.

The present invention is also directed to a method for stepping out of function calls in software executing on a target processor. This method involves setting one or more break points in the software to be executed, updating the program storage as required by the break points set, setting the debug mode to step-out, setting the call level counter register to zero, setting the program counter to the first point of desired execution in the program, starting execution of the program, halting program execution when the call level counter becomes less than zero, and reading and correcting the program counter.

These and other features, aspects, and advantages of the present invention will become better understood with reference to the following description and appended claims.

### BRIEF DESCRIPTION OF THE DRAWINGS

FIG. 1 shows a general debug environment for an integrated circuit chip.

FIG. 2 shows a register-level view of a debug module and related connections to an emulator and a target processor of FIG. 1 to debug.

FIG. 3 shows the register-level view of the break point controlling portions of the debug module of FIG. 2 and connections to program storage and the target processor.

FIG. 4 depicts a state flow diagram for a flow control state machine within the debug module of FIG. 2.

FIG. 5A shows process steps for a step-over method of debugging.

FIG. 5B shows further details for implementing the process step in FIG. 5A of scanning program storage for set break points.

FIG. 5C depicts further details for implementing the process step of FIG. 5A of starting program execution.

FIG. 6A shows process steps for a step-out method of debugging.

FIG. 6B depicts further details for implementing a call to the step-over method from within the step-out method.

### BEST MODE FOR CARRYING OUT THE INVENTION

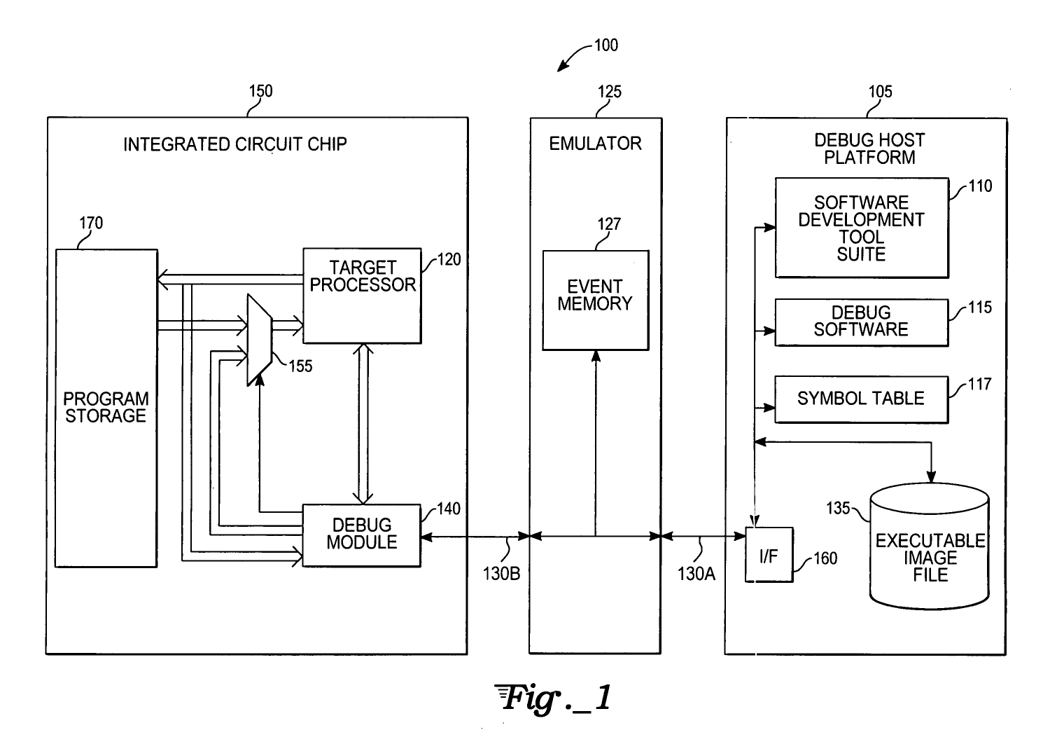

With respect to FIG. 1, an exemplary embodiment of a general debug environment 100 is shown. The present embodiment of the general debug environment 100 includes a debug host platform 105 connected to an emulator 125. The emulator 125 is connected to an integrated circuit chip 150 containing a target processor 120 executing the program to be debugged.

The debug host platform 105, in the form of, for example, a personal computer, contains a general programming environment comprised of a software development tool suite 110 and a debug software application 115. An executable image file 135 is accessible by the software development tool suite 110 and the debug software 115. The debug software uses information from the image file 135 to build a symbol table 117. The symbol table contains, amongst other things, the addresses of the high-level instructions in the program to be debugged. These addresses are used during debugging as symbolic break points. The debug host platform 105, through internal connections and devices (not shown), couples the software development tool suite 110 and debug software 115 to an interface (I/F) 160, which couples to the emulator 125 through a connection bus 130A. The emulator may contain an event memory 127 containing a copy of all or part of the symbol table 117. The connection between the debug host platform 105 interface 160 and the emulator 125 could be, for example, an RS232 bus, a Universal Serial Bus (USB), or fiber optic connection.

The integrated circuit chip 150 contains a debug module 140, a target processor 120, and a program storage 170. The emulator 125 connects to the integrated circuit chip 150 by a bus connection 130B through the debug module 140. The debug module 140 connects to the target processor 120 directly and through a multiplexer 155. The target processor 120 also connects to the program storage 170.

Within the debug host platform 105, the debug software 115 provides a user with a graphical interface composed of windows (not shown), each window representing a different view of a debugging process. The debug software 115 is integrated with other applications, such as the software development tool suite 110, to form a general programming environment, which a user can use to determine proper program operation of code executing on the target processor 120.

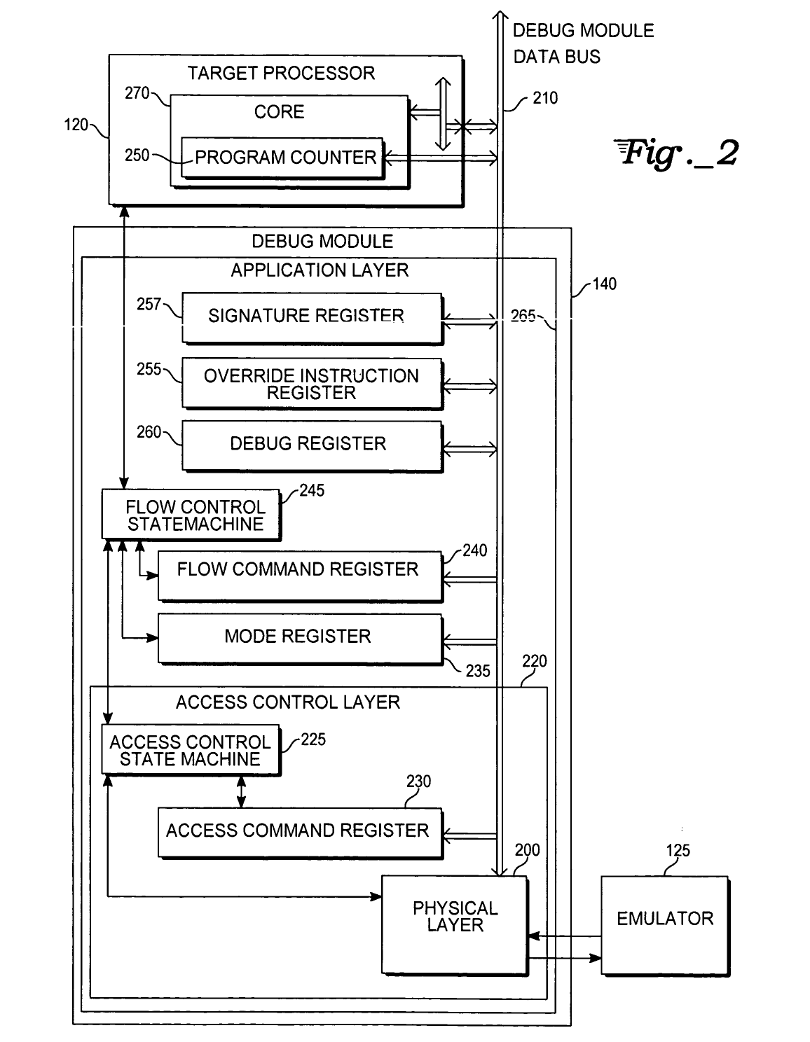

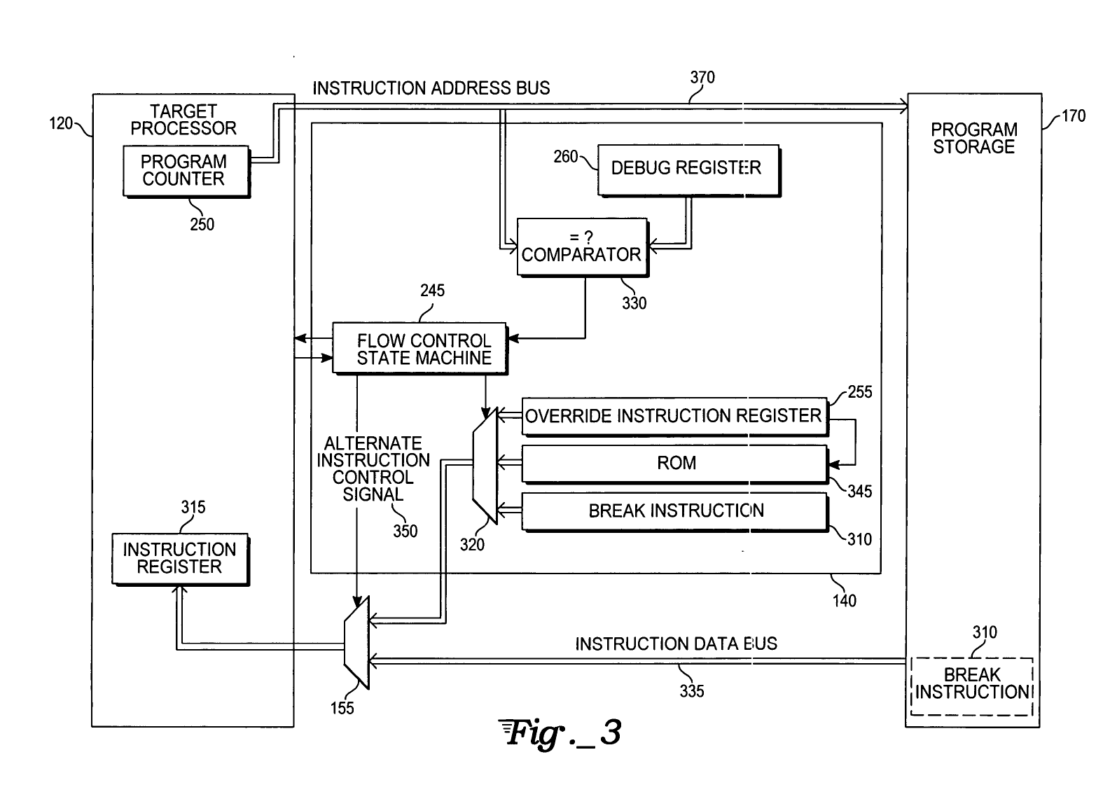

The target processor 120 may generally contain a program counter 250 (FIG. 2), a program stack (not shown), an instruction register 315 (FIG. 3), a plurality of general purpose registers (not shown), and a local memory (not shown). The debug software 115 will control program execution by the target processor 120, in part, by setting break points, setting watch points (data break points), single stepping at a source code instruction level, single stepping at a machine code level, or by providing fault detection support. Debug software 115 interrogates the target processor 120 to present views of the stack, the registers, a machine state, and the code to be executed in the program storage 170. Additionally, the debug software 115 may modify values in the program counter 250, the stack, the general purpose registers, or the program storage 170 for making proposed changes to correct any problems found.

FIG. 2 shows the emulator 125 connecting with a physical layer 200 of the debug module 140. The physical layer 200 maintains communication details of synchronization so that the emulator 125 can transmit data and commands to an internal debug module data bus 210 and receive data from the debug module data bus 210 and various connected registers (described infra). The physical layer 200 also connects to an access control state machine 225 of an access control layer 220 to jointly coordinate how commands will be entered to an access command register 230. The access command register 230 is connected to the debug module data bus 210.

The access control state machine 225 is connected to a flow control state machine 245 in an application layer 265. The access control state machine 225 is used for managing an access command state (not shown) and coordinating command state information with the flow control state machine 245. A flow command register 240 and a mode register 235 are connected to the flow control state machine 245 so that their contents can direct the flow control state machine 245. The flow control state machine 245 is further connected to an interface (not shown) on the target processor 120 for control of execution to be carried out.

The application layer 265 contains a signature register 257, which is used by the debug software 115 to identify the device being debugged. An override instruction register 255 is located in the application layer 265 so that the emulator 125 can send intervening instructions to the target processor 120 without having to update the program storage 170 each time a program restart or single step from a location containing a Break instruction 310 is desired. During debug operations, a debug register 260, will contain either an address of a break point or a count of functions called. The count of called functions will be incremented and decremented in the debug register 260 as function calls are entered or returned from respectively, during debug. The signature register 257, the override instruction register 255, and the debug register 260 are each connected to the debug module data bus 210. A core 270 within the target processor 120 is connected to the debug module 140 by the debug module data bus 210. A program counter 250 inside the core 270 is accessed by the debug module 140 to observe and control the program location being executed by the target processor 120.

In FIG. 3 an exemplary embodiment of program storage 170 is shown, for example, by FLASH Memory. The program storage 170 may also be implemented for example, in SRAM, DRAM, a memory hierarchy of one or more caches in connection with a main memory, a virtual memory system incorporating disk drive storage, or a combination of storage media. The program storage 170 device is connected to the target processor 120 by an instruction data bus connection 335. A break instruction 310 can be directly programmed into the executable image file 135 (FIG. 1) by the user or inserted by the emulator as an application break point. The program storage 170 is connected to a first multiplexer 155. An output of the first multiplexer 155 is connected to an instruction register 315 within the target processor 120.

The instruction address bus 370 connects the program counter 250 of the target processor 120 to the program storage 170, and a comparator 330. An output of the debug register 260 and the instruction address bus 370 are inputs to the comparator 330, whose output is connected to the flow control state machine 245. Program counter 250 addresses are put on the instruction address bus 370 in the course of program execution and can be compared to an address in the debug register 260. When an address on the instruction address bus 370 matches the address stored in the debug register 260, a signal is sent to the flow control state machine 245 to halt target processor 120 execution by forcing a hardwired break instruction 310 to the instruction register 315 if enabled in the present mode of operation as given by the mode register 235.

An output of the override instruction register 255 is connected to a second multiplexer 320, which is controlled by the flow control state machine 245. The second multiplexer 320 is also fed by a general purpose program storage, for example, a ROM 345 and a hardwired break instruction 310. The general purpose program storage could also be configured with a FLASH device, an EPROM or an SRAM. The content of the override instruction register 255 depends on the mode of operation. The override instruction register can provide an alternate instruction source or select a program type within the ROM 345. Under control of the flow control state machine 245 any of these input quantities to the second multiplexer 320 can be fed to the first multiplexer 155 and from there to the instruction register 315 of the target processor 120 when an alternate instruction control signal 350 is selected from the flow control state machine 245.

The various register elements and control state machine combinations, are well known to one skilled in the art, to be capable of implementation by any number of circuit combinations of, for example, flip-flops, flip-flops with clocked latches, microsequencer with programmable control memory and state registers, or latching storage elements with combinatorial circuitry.

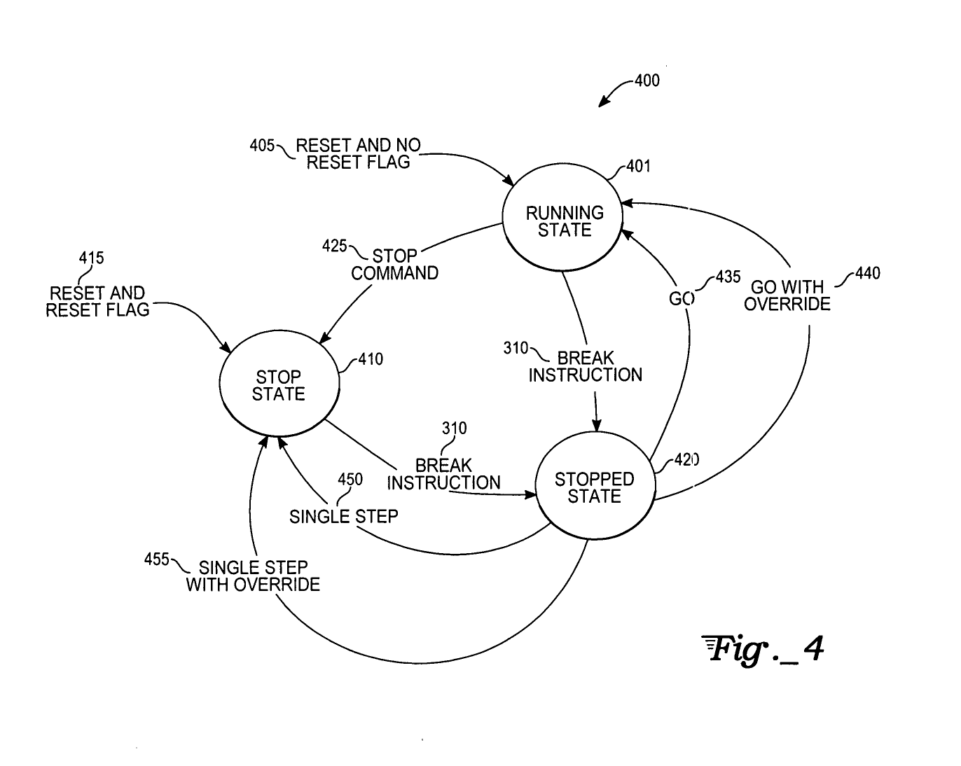

FIG. 4 shows a state transition function diagram 400 managed by the flow control state machine 245. The three states represented are a stop state 410, a stopped state 420, and a running state 401. The stop state 410 is equivalent to the condition of stopping and the stopped state 420 designates that the program flow is completely stopped. The running state 401 denotes a regular program execution condition. The running state 401 is the default system state on power up. An external event reset and reset flag 415 feeds the stop state 410. The stopped state 420 may be reached from the stop state 410 when a break instruction 310 is executed bV the target processor 120. The stop state 410 is reached from the stopped state 420 by either a single step 450 or a single step with override 455 flow control command being executed. The stop state 410 is also reached from the running state 401 when a stop command 425 is issued by the debug software 115.

The stopped state 420 is also reached from the running state 401 when a break instruction 310 is executed during program code execution. From the stopped state 420 program execution may be resumed by a go command 435 or go with override 440 command, either of which will create a transition to the running state 401. The running state 401 is also reached when the external event reset and no reset flag 405 is set.

The following table denotes an exemplary set of command byte codes that are relevant to the present invention. Note that some byte codes not set forth may also be reserved for future use.

Command Byte Codes

| Command bits | | | | | | | | Command or Instruction |
|---|---|---|---|---|---|---|---|---|
| 7 | 6 | 5 | 4 | 3 | 2 | 1 | 0 | Flow Control Commands |
| 0 | 0 | x | x | 0 | 0 | 0 | 0 | Go |
| 0 | 0 | x | x | 0 | 0 | 0 | 1 | Single-Step |
| 0 | 0 | x | x | 0 | 0 | 1 | 0 | Go with Override |
| 0 | 0 | x | x | 0 | 0 | 1 | 1 | Single-Step with Override |
| 0 | 0 | x | x | 0 | 1 | 0 | 1 | Stop |
| 0 | 0 | x | x | 0 | 1 | 1 | 0 | Reset and debug module disabled |
| 0 | 0 | x | x | 0 | 1 | 1 | 1 | Reset |

Communication Control

| | | | | | | | | |
|---|---|---|---|---|---|---|---|---|
| 0 | 0 | 0 | 0 | x | x | x | x | Goto Command Mode |
| 0 | 0 | 1 | 0 | x | x | x | x | Goto CPU Mode |
| 0 | 0 | 1 | 1 | x | x | x | x | Goto IDLE Mode |

General and Debug Modes

| | | | | | | | | |
|---|---|---|---|---|---|---|---|---|
| 0 | 1 | x | x | x | 0 | 0 | 0 | Normal |
| 0 | 1 | x | x | x | 0 | 0 | 1 | Normal with Break Point |
| 0 | 1 | x | x | x | 0 | 1 | 0 | Step Over |
| 0 | 1 | x | x | x | 0 | 1 | 1 | Step Out |
| 0 | 1 | x | x | x | 1 | 0 | 0 | Monitor |
| 0 | 1 | x | x | x | 1 | 0 | 1 | Monitor with Break Point |

Flow Control Settings

| | | | | | | | | |
|---|---|---|---|---|---|---|---|---|
| 0 | 1 | x | x | 1 | x | x | x | Break on Interrupt |
| 0 | 1 | x | 1 | x | x | x | x | Break on Change of Flow |

Register Access

| | | | | | | | | |
|---|---|---|---|---|---|---|---|---|
| 1 | 1 | x | x | 0 | 0 | 0 | 0 | Program Counter |
| 1 | 1 | x | x | 0 | 0 | 0 | 1 | Debug Register |
| 1 | 1 | x | x | 0 | 0 | 1 | 0 | Override Instruction |

Access Mode

| | | | | | | | | |
|---|---|---|---|---|---|---|---|---|
| 1 | 1 | 0 | x | x | x | x | x | Write Access |
| 1 | 1 | 1 | x | x | x | x | x | Read Access |

In another exemplary embodiment of the present invention, a debug software program 115 and software development tool suite 110 are configured as shown in FIG. 1 along with an executable image file 135 to be debugged. An emulator 125, a debug host platform 105, a debug application, and a target processor 120 are connected as shown in FIG. 1. A debug session is initiated on the debug host platform 105 and the connection to the target processor 120 is verified including any configuration settings necessary to make connection to the debug module 140. The executable image file 135 is loaded to the program storage area 170; which in the present embodiment is FLASH Memory located onboard the integrated circuit chip 150 with the target processor 120. From the debug software 115 view of the program, which could be a programming language source code view, the program is marked with one or more break points at address locations of interest. The code to be executed may contain function calls or nested function calls within the span of code under consideration. The step over and step out methods of the present exemplary embodiment are emulator 125 implementations, working with the apparatus previously stated, operating under the debug software 115 configuration.

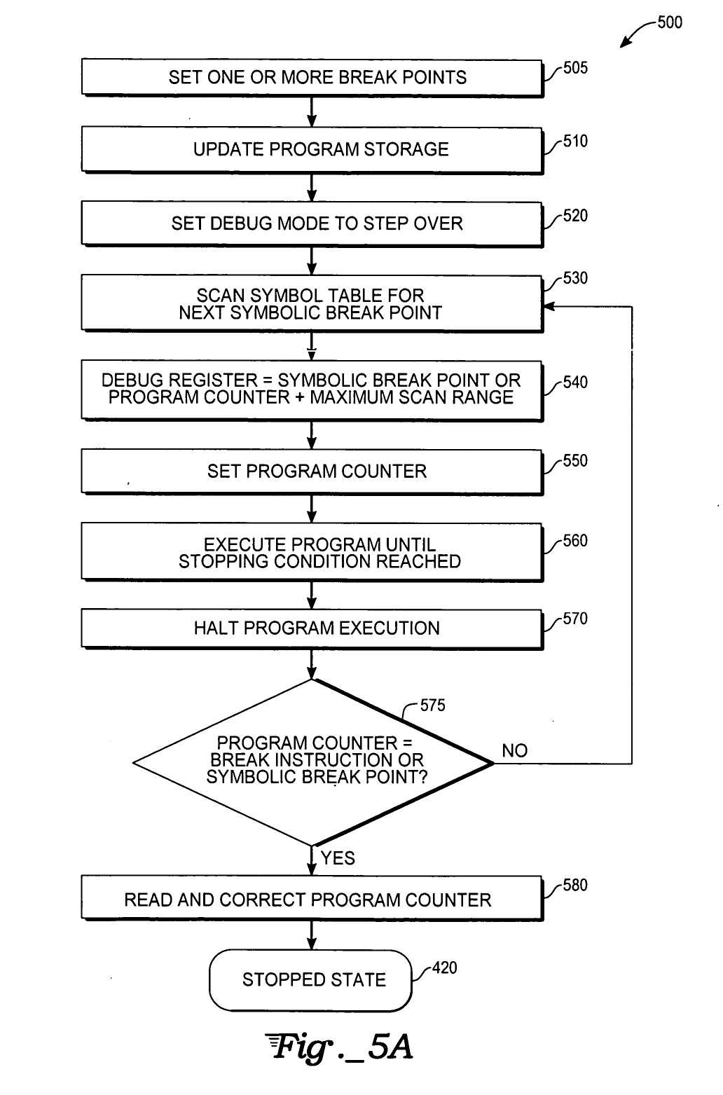

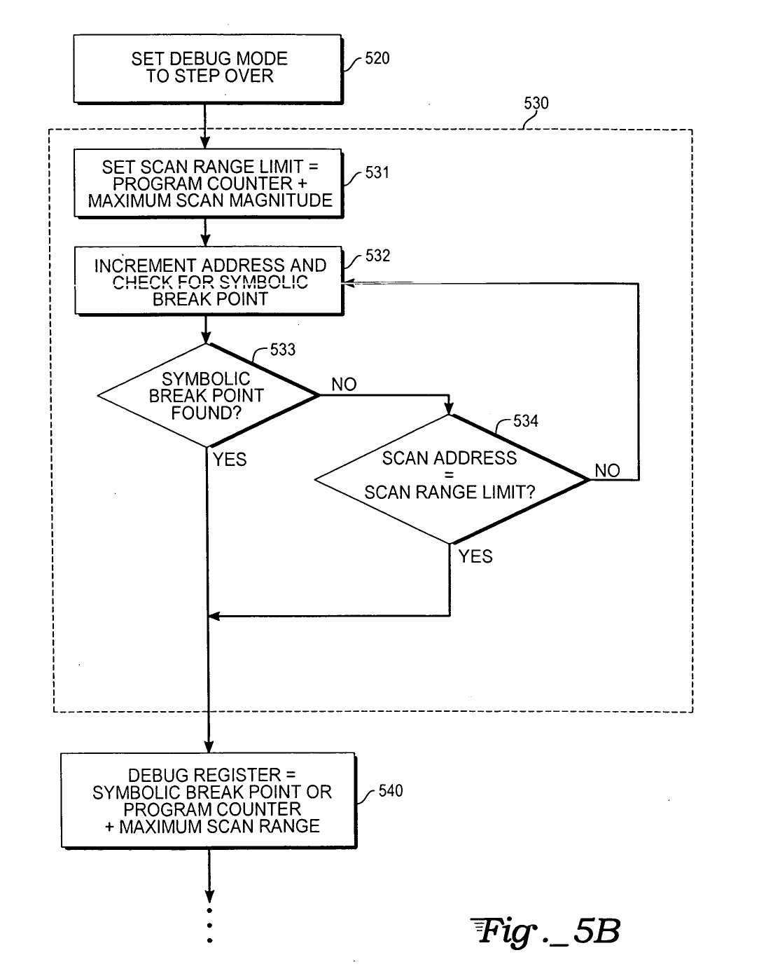

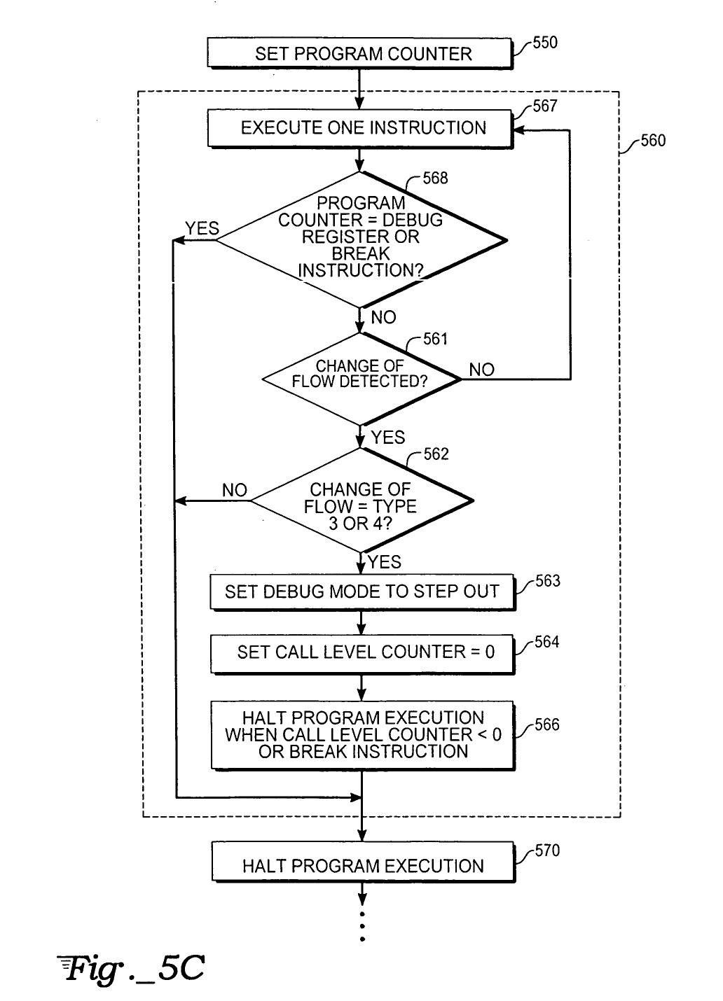

FIG. 5A shows an exemplary embodiment of a process flow diagram for a step over method 500. The step over method 500 includes the process of setting one or more application break points 505 of interest, updating 510 the program storage 170 with the one or more Break instructions 310 at the application break point addresses found in the set one or more application break points step 505, setting the debug mode to step over 520, scanning the symbol table 117 for any sequential symbolic break point that may occur after the current program counter 530. The symbol table 117, of the scanning step 530, may reside in the debug host platform 105 or in the event memory 127. The step over method 500 continues with setting 540 the debug register 260 equal to any symbolic break point found or the program counter plus the maximum scan range, setting 550 the program counter 250, executing the program 560 until a stopping condition is reached, halting program execution 570, determining whether a symbolic break point or a break instruction 575 does not exist at the current program counter address, in which case the operation is iterated from the scanning stage 530. If a symbolic break point or a break instruction 575 does exist, the process continues by reading and correcting 580 the program counter 250, and the step of entering the stopped state 420.

FIG. 5B shows a more detailed exemplary embodiment of a process flow diagram of the method scan symbol table 117 for break points set 530. After the step of set debug mode to step over 520, the general scanning process includes a process of setting a scan range limit equal to the current program counter 250 plus a maximum scan magnitude 531, and incrementing the address and checking for a symbolic break point 532. If a symbolic break point is found 533 then a process of setting the debug register 260 to break point address found 540 is taken. If no break point is found 533 then a step of checking whether a scan address equals the scan range limit 534 is performed. If the scan address equals the scan range limit 534, then a process of setting 540 the debug register 260 is taken; in this case setting the debug register 260 to the value of the program counter 250 contents plus the maximum scan range. If the scan address does not equal the scan range limit 534, the process iterates with incrementing the address and checking for a symbolic break point 532. The method allows a user to set the maximum scan magnitude 531 that optimizes between too frequent of stops in execution and too lengthy of emulator 125 or debug software 115 scan time. An exemplary range of the maximum scan magnitude 531 setting is from 20 to 100 program locations, inclusive.

Nominally, changes in the sequential flow of instructions can, for example, be categorized in an exemplary embodiment as follows:

Instruction Category
1. Jump, skip, and branch instructions;
2. Return;
3. Call; and
4. Interrupt acknowledge.

When the debug mode is not either step over or step out, the first 3 categories are controlled by a flow control setting of break on change of flow and the last category is controlled by a break on interrupt flow control setting (refer to Command Byte Code Table, Flow Control Settings). The step over mode takes special control of these categories. In step over mode categories 1 and 2 are enabled but 3 and 4 are used to manage the full speed execution of code over function calls and hardware interrupts.

FIG. 5C shows an exemplary embodiment of the start program execution 560 method. Following the process of setting 550 the program counter 250, execution of instructions in categories 3 and 4 will be distinguished by hardware in the start program execution process. The start program execution method includes a step of execute one instruction 567 and a step of determining whether the program counter equals the debug register or the instruction is a Break instruction 568. A next step is to halt program execution 570 when the program counter 250 equals the debug register 260 or the instruction being executed is a Break instruction. If the program counter 250 does not equal the debug register 260 and the program counter is not positioned to execute a Break instruction, a next step is determining whether a change of flow has been detected 561. If determining a change of flow detected 561 is false, the process returns to the step of execute one instruction 567. If determining a change of flow detected 561 is true, then the process includes checking if a change of flow 562 due to a call instruction or an interrupt acknowledge has been detected. If the category of instruction is not a call instruction (type 3) or interrupt acknowledge (type 4) (i.e., it must be a type 1 or type 2) program execution is halted 570, otherwise the determination of a change of flow due to an instruction category of type 3 or type 4 is true and the method continues with setting the debug mode to step out 563, setting the call level counter to zero 564, executing at full speed until the call level counter becomes less than zero 566 or a Break instruction is executed, and then execution is halted 570.

Continuing execution in the step out mode allows for nested levels of function calls to be executed continuously at full processor speed and without intervention until returning to the calling location. This is facilitated by the debug register use changing from storing a break point to storing an up-down count during call level counting in nested function calls.

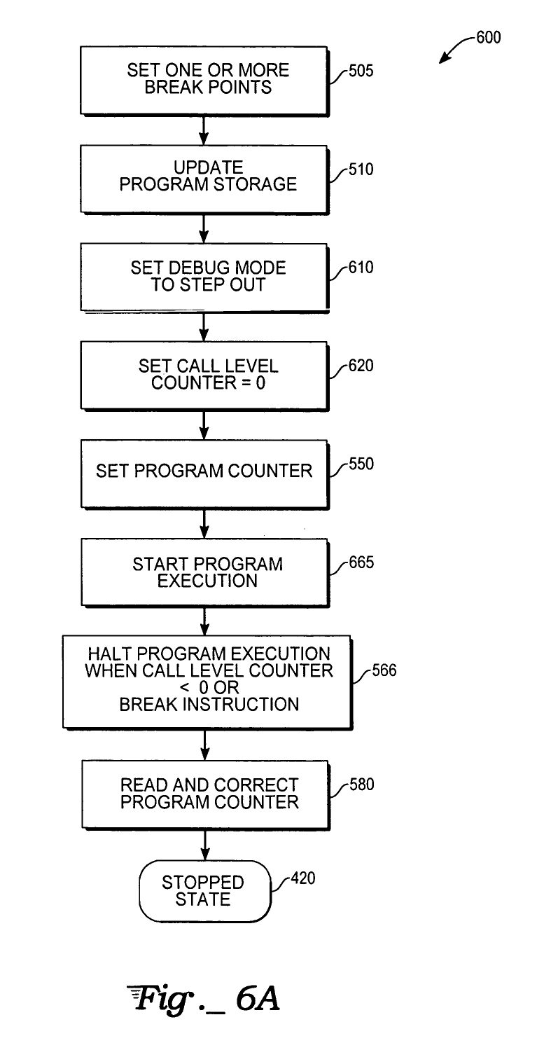

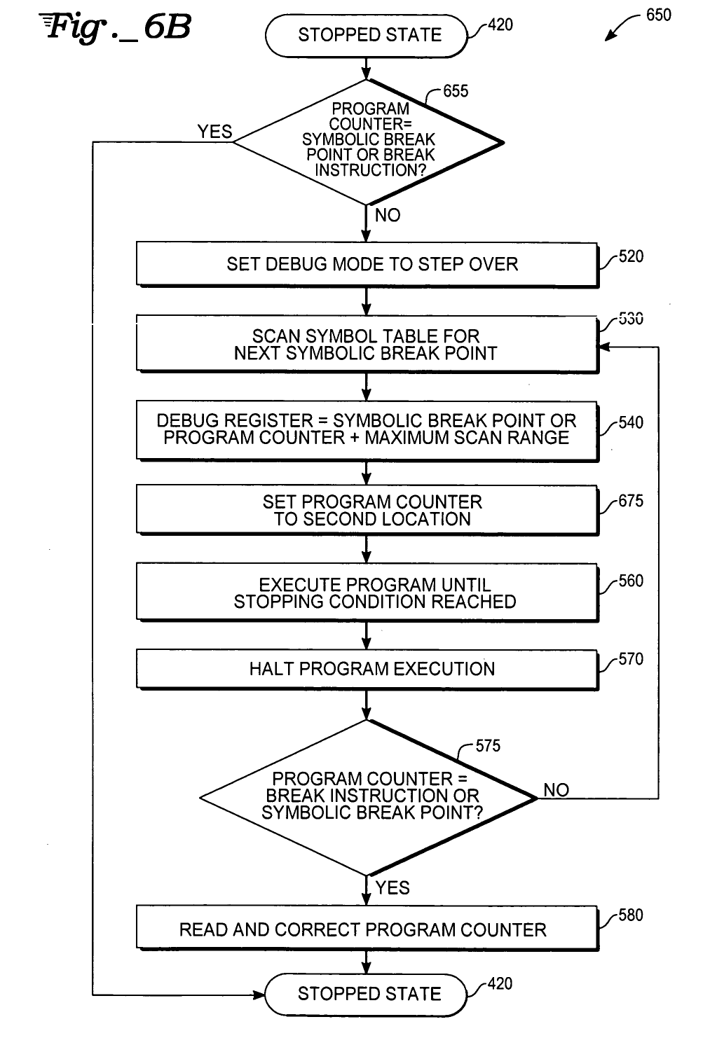

FIG. 6A shows an exemplary process flow diagram for a step out method 600. The step out method includes setting one or more break points 505 of interest, updating 510 the program storage 170 with the one or more Break instructions 310 at the application break point addresses found in the set one or more break points step 505, setting the debug mode to step out 610, setting the call level counter equal to zero 620, setting the program counter 250 equal to the desired address 550, starting program execution 665, halting program execution when the call level counter is less than zero 566 or a Break instruction is executed, reading and correcting 580 the program counter 250, and the step of entering the stopped state 420.

Change of flow break points are disabled in the step out mode allowing for function calls and hardware interrupt handler code to be executed at full speed until the debug register 260 contents becoming less than zero signals a completion of execution and return back to the calling point in the code. The management of calling program levels is done by incrementing the call level counter value in the debug register 260 with each function called or interrupt service routine invoked and decrementing it with each return from a called function or an invoked interrupt service routine. When the count becomes less than zero, execution has returned to the calling location and recursive function calls have been properly handled. The value in the debug register 260 being less than zero will cause the flow control state machine 245 to create a break in execution.

FIG. 6B shows an exemplary process flow diagram for a call to a step over method 650 that begins from the stopped state 420 of the step out method 600 (FIG. 6A). The call to the step over method 650 includes the process of determining whether a Break instruction or a symbolic break point is present at the current program counter location 655. If either of these two conditions are true, the step of entering the stopped state 420 is taken. If no break point is found, then execution must be in the midst of an expression or program statement when the function call was made. If no break point is found, the method includes the step of setting the debug mode to step over 520, scanning the symbol table 117 for any sequential symbolic break point that may occur after the current program counter 530. The symbol table 117, of the scanning step 530, may reside in the debug host platform 105 or in the event memory 127. The step over method 650 continues with setting 540 the debug register 260 equal to any symbolic break point found or the program counter plus the maximum scan range, setting 675 the program counter 250 to a second location of interest, executing the program 560 until a stopping condition is reached, halting program execution 570, determining whether a symbolic break point or a break instruction 575 does not exist at the current program counter address, in which case the operation is iterated from the scanning stage 530, otherwise the process continues by reading and correcting 580 the program counter 250, and the step of entering the stopped state 420.

FIGS. 6A and 6B taken together, show how to address recursive function calls that may be encountered when stepping through a function call occurring in the middle of a programming statement.

Although the present invention has been described in terms of exemplary embodiments, one skilled in the art will recognize that additional embodiments could readily be conceived which will still be within a scope of the present invention. For example, particular process flow diagrams, debug system diagrams, and integrated processor systems are presented as exemplary embodiments of approaches for implementing these stepping methods. However, a skilled artisan could readily rearrange certain steps within the process flow diagrams, implement alternative debug systems, employ different emulator systems, use alternate integrated development environments (IDEs) for software investigation, incorporate different bus structures coupling storage elements in a communication hierarchy, and achieve the same result of determining break points and running executable image files 135 at full speed. Therefore, the scope of the present invention shall only be limited by the appended claims.

1. A debug module for managing execution of software on a target processor during debug comprising:
a communication management means for coupling with an emulator whereby a plurality of debug information is received by an access management means, said access management means configured to establish communication control, register identification, and mode control in debug processes, said plurality of debug information is further configured to be received by a flow management means, an operation of said target processor is managed by said flow management means through receipt of a plurality of flow commands, mode settings, and processor instruction data configured to control the execution of said target processor.

2. The debug module of claim 1, further comprising:
a receiving means for receiving commands and input data from said emulator, an output means for sending output data to said emulator, wherein said receiving means and said output means are electrically coupled to a plurality of storage means within each of said communication management means, said access management means, said flow management means, and said target processor.

3. The debug module of claim 1, wherein said access management means further comprises:
an access command storage means for retaining a plurality of access commands, said access command storage means being coupled to an access control means for controlling communication and access to said access command storage means, said access control means being electrically coupled to said access command storage means, said communication management means, and a flow control means within said flow management means.

4. The debug module of claim 1, wherein said flow management means further comprises:
an override instruction storage means for retaining override instructions, a flow command storage means for retaining flow commands, a mode control storage means for retaining mode control commands, a debug storage means for retaining debug information, and a device signature storage means for retaining an identity of a device to be debugged, wherein said override instruction storage means, said flow command storage means, said mode control storage means, said debug storage means, and said device signature storage means are electrically coupled to one another.

5. The debug module of claim 4, wherein said flow management means further comprises a flow control means for controlling processor execution, wherein said flow control means is electrically coupled to said flow command storage means, said mode control storage, said target processor, and an access control means located within said access management means, said flow management means further comprises a comparative means for determining equal quantities, said comparative means having inputs electrically coupled to said debug storage means and a program counting means within said target processor, said debug storage means and said program counting means configured as input quantities to be compared by said comparative means, said comparative means having an output electrically coupled to said flow control means, said comparative means configured to receive said input quantities and providing a result to said flow control means for determining a controlling action.

6. The debug module of claim 4, wherein said override instruction storage means is configured to retain, in sequence, a plurality of alternative override instructions, said override instruction storage being in communication with said emulator, said emulator sends said override instructions to said override instruction storage means for execution on said target processor.

7. The debug module of claim 6, wherein said override instruction storage means is coupled to said emulator and an instruction storage means configured for retaining a plurality of target processor instructions, a content of said override instruction storage means select a program type within said instruction storage means.

8. A debug module for managing execution of software on a target processor during debug comprising:
a physical layer configured to couple said debug module to an emulator for a debug information exchange;
an access control layer configured to receive communication control commands, register identification, and mode control commands from said emulator, said access control layer further configured to implement access to said debug module; and
an application layer configured to receive commands, mode settings, and processor instruction data from said emulator, said application layer further configured to manage an operation of said target processor.

9. The debug module of claim 8, further comprising an input terminal for receiving commands and input data from said emulator, an output terminal for sending output data to said emulator, and a data bus coupling one or more registers within each of said physical layer, said access control layer, said application layer, and said target processor.

10. The debug module of claim 8, wherein said access control layer further comprises an access command register connected to said data bus for holding a plurality of access commands and an access control state machine for controlling communication and register access, said access control state machine being electrically coupled to said access command register, said physical layer, and a flow control state machine located within said application layer.

11. The debug module of claim 8, wherein said application layer further comprises an override instruction register, a flow command register, a mode register, a debug register, and a signature register for retaining an identity of a device to be debugged, wherein said override instruction register, said flow command register, said mode register, said debug register, and said signature register are coupled to said data bus.

12. The debug module of claim 11, wherein said application layer further comprises a flow control state machine for controlling processor execution states, wherein said flow control state machine is electrically coupled to said flow command register, said mode register, said target processor, and an access control state machine located within said access control layer, wherein said application layer further comprises a comparator circuit with input connections coming from said data bus and said debug register and an output comparison result electrically coupled to said flow control state machine.

13. The debug module of claim 11, wherein said override instruction register can be configured to handle, in sequence, a plurality of alternative override instructions providing program control by commands from said emulator, avoiding program storage updates and said plurality of alternative override instructions can be used to provide selective program invocation of alternate program sources within a program storage space.

14. A method for stepping over function calls in a program executing on a target processor comprising:
setting one or more break points in said program to be executed;
updating a program storage as required by said setting one or more break points step;
setting a debug mode to step over;
scanning a symbol table for a next halting address;
setting a content of a debug register to said next halting address;
executing said program until a first execution halting condition is reached;
halting said execution of said program;
determining a valid break condition of said first execution halting condition;
iterating a portion of said method for stepping over if said determining a valid break condition step is negative; and
reading and correcting a program counter if said determining a valid break condition step is positive.

15. The stepping method of claim 14, wherein said scanning step further comprises scanning from a current program location to a first occurrence of either a next one of said one or more break points or a scan range limit.

16. The scanning step of claim 15, wherein said scan range limit is set by a maximum scan magnitude added to said current program location, said maximum scan magnitude being a number of program locations to scan in a scanning iteration, wherein said maximum scan magnitude is set to optimize scanning time.

17. The stepping method of claim 14, wherein said setting a content step further comprises setting said content of said debug register to an address of any next one of said one or more break points found in said scanning step or an address of said program counter plus a maximum scan range.

18. The stepping method of claim 14, wherein said first execution halting condition further comprises said program counter indicating an execution of a break in execution instruction or a next one of said one or more break points.

19. The stepping method of claim 14, wherein said iterating a portion step further comprises continuing execution at said scanning step.

20. The stepping method of claim 14, wherein said setting a content step further comprises setting an override instruction register as may be prescribed by an emulator for controlling further debug execution alternatives and program type selections, said debug execution alternatives and program type selections being capable of execution without need of updating a program storage.

21. The stepping method of claim 14, wherein said updating a program storage step further comprises accessing a signature register for retrieving of an identifying signature of a component to debug.

22. The stepping method of claim 14, wherein said executing said program step further comprises:
executing an instruction;
determining if a valid halting address is reached;
completing said executing said program step if said determining a valid halting address step is positive;
determining whether a change of a flow in said execution of said program is detected if said determining a valid halting address step is negative;
iterating a portion of said executing said program step if said determining a change of a flow step is negative;
determining a valid condition type of an instruction if said determining a change of a flow step is positive;
completing said executing said program step if said determining a valid condition type step is negative;
setting said debug mode to step out if said determining a valid condition type step is positive;
setting a content of a call level counter register to zero; and
executing said program until a second execution halting condition is reached.

23. The stepping method of claim 22, wherein said valid halting address further comprises said program counter either equaling said debug register contents or indicating an execution of a break in execution instruction.

24. The stepping method of claim 22, wherein said iterating a portion step further comprises commencing at said executing an instruction step.

25. The stepping method of claim 22, wherein said valid condition type further comprises a call instruction or an interrupt request.

26. The executing said program step of claim 22, wherein said second halting execution condition further comprises said call level counter being less than zero or executing a break in execution instruction.

27. A method for stepping out of function calls in a program executing on a target processor comprising:
setting one or more break points in said program to be executed;
updating a program storage as required by said setting one or more break points step;
setting a debug mode to step out;
setting a content of a call level counter register to zero;
starting execution of said program;
executing said program until a first execution halting condition is reached; and
reading and correcting a program counter.

28. The stepping method of claim 27, wherein said execution halting condition further comprises a detection of said call level counter becoming less than zero or said program counter indicating an execution of a break instruction.

29. The stepping method of claim 27, wherein said executing said program step further comprises:
commencing from a state of stopped execution on said target processor;
determining a valid break condition of said first execution halting condition;
completing said executing said program step if said determining a valid break condition step is positive;
setting a debug mode to a method of stepping over if said determining a valid break condition is negative;
scanning a symbol table for a next halting address;
setting a content of a debug register to said next halting address;
executing said program until a second execution halting condition is reached;
halting said execution of said program;
determining a valid break condition of said second execution halting condition;
iterating a portion of said method for stepping over if said determining a valid break condition step is negative; and
reading and correcting a program counter if said determining a valid break condition step is positive.

30. The stepping method of claim 29, wherein said scanning step further comprises scanning from a current program location to a first occurrence of either a next one of said one or more break points or a scan range limit.

31. The scanning step of claim 30, wherein said scan range limit is set by a maximum scan magnitude added to said current program location, said maximum scan magnitude being a number of program locations to scan in a scanning iteration, wherein said maximum scan magnitude is set to optimize scanning time.

32. The stepping method of claim 29, wherein said setting a content step further comprises setting said content of said debug register to an address of any next one of said one or more break points found in said scanning step or an address of said program counter plus a maximum scan range.

33. The stepping method of claim 29, wherein said second execution halting condition further comprises said program counter indicating an execution of a break in execution instruction or a next one of said one or more break points.

34. The stepping method of claim 29, wherein said iterating a portion step further comprises continuing execution at said scanning step.

35. The stepping method of claim 29, wherein said setting a content step further comprises setting an override instruction register as may be prescribed by an emulator for controlling further debug execution alternatives and program type selections, said debug execution alternatives and program type selections being capable of execution without need of updating a program storage.
